(19) United States
(12) Patent Application Publication
(10) Pub. No.: US 2008/0316915 A1
(43) Pub. Date: Dec. 25, 2008

(54) Method & apparatus for identifying the cause of communication session faults

(75) Inventors: Jacob Skovborg Just, Horsens (DK); Stephan Korsholm, Horsens (DK)

Correspondence Address: ROBERT C. SCHLUER, 45 GROTON ROAD, SHIRLEY, MA, 01464, US

(73) Assignee: POLYCOM, INC.

(21) Appl. No.: 11/821,550

(22) Filed: Jun. 22, 2007

(51) Int. Cl. G01R 31/08

(52) U.S. Cl. 370/216

(57) ABSTRACT

A communication network includes a wireless LAN and associated wireless communication devices and a computational device either located remotely from the wireless LAN or located in the wireless LAN. The wireless communication devices operate to conduct communication sessions with other communication devices associated with the communication network and they operate to log communication session event activity. In the event that a communication session being run by a wireless communication device unexpectedly ends due to a fault event, the wireless communications device is capable of sending the entire contents of the logged communication session to the computational device for analysis to determine the cause of the fault event. The computational device operates to run a virtual communication session under the control of a debug module such that the session can be stopped at any time to examine the contents of the virtual communication session.

### FIELD OF THE INVENTION

My invention relates generally to the area of network communication technology and specifically to the area of logging the contents of a communication session for later analysis to identify the cause of session errors at a communication device operating in a communications network.

### BACKGROUND OF INVENTION

As communication devices, that are employed to transmit and receive voice, data or video information or some combination thereof, become more complex in order to support the rapidly increasing functionality available on communication networks, the communication devices themselves necessarily have to become more complex. This complexity is manifested in these communications devices by additional and more complex applications or functional modules being added. With the addition of more complexity to the communication devices, there is a greater risk that a fault event can occur during the course of a communication session that may have the effect of denigrating the quality of the session, or worse, prematurely ending the session all together. Further, if a communication device is of the wireless type, there is even greater risk that a fault event may occur during a communication session. These fault events can be the result of application software or firmware bugs, network errors, or in the case of wireless communication devices they can be the result of poor signal quality as the device roams away from a signal source or a fault during the process of roaming from the range of one signal source, such as a base station or access point, to within range of another signal source.

A number of troubleshooting techniques are employed by network operators to identify the cause of such fault events. One common technique is to run a “trace” on the type of message being sent during the time of the fault event. This technique is initiated by turning on trace functionality residing at some or all of the nodes in a network that is responsible for handling the message. This trace functionality identifies and logs the messages as they are processed by each of the nodes and the logs can be reviewed later by the network operator to determine where the fault was created. Depending upon the number of nodes involved with the trace and the number of different message types being traced, a large volume of information can be stored in a trace log for review by a network operator. This can be a daunting, time intensive task for the operator.

United States patent application 2005/0276385 (McCormick et al.) describes one technique for controlling communication session fault event logging by using “triggers” to initiate the logging of communication session events precipitated by signal tracing activity. Starting on page 4, paragraph 45 of this application is a description of the use of an “event logging trigger” mechanism that initiates the logging of session information once the trigger is activated. Session information can be logged for the remainder of the session and later transmitted to a remote location for examination as described on page 5, paragraph 66 of this application. While the use of an event trigger limits the quantity of session information logged as the result of running a signal or protocol trace, making it easier for the operator to determine the cause of the fault, and while transmitting the record of logged session events to a remote device reduces the amount of work and simplifies the operators troubleshooting responsibilities, the technique is complicated by the necessity of the network operator having to run a trace and to select and include trigger commands in messages used to test the network operation. Further, although the technique of using triggers reduces the amount of event information to be subsequently analyzed, it may not record all of the information necessary to accurately analyze the fault event.

United States patent application 2006/0211415 (Cassett et al.) describes a technique used to mitigate the amount of activity that is logged by a wireless communication device and then transmit the logged information to another device in the network for analysis. Specifically, on page 3, starting in paragraph 26 is described a malfunction management module that generates and transmits to a wireless device tracking configuration parameters which the wireless device employs to track and log events of interest to a network operator. The configuration parameter can identify a particular malfunction event parameter which may be a crash event, a freeze event, a reset event and so forth. The tracking configuration may log single events, input information, values or message information, or predetermined sequences or combinations of events, for example. This logged event information is stored at the wireless device and can be later selectively transmitted to another device on the network for analysis as described on page 4 in paragraph 32. Although this logging technique does reduce the amount of logged event information and allows for this information to be transmitted to a remote device for analysis, it still requires a network operator to periodically create and then transmit to one or more wireless devices in the network tracking configuration instructions that enable the wireless devices to log particular types of malfunctions. Then, after receiving the logged information the process requires that the network operator determine as the result of viewing log information what the cause of the malfunction is. Further, and similarly as with the McCormick et al. application, the Cassett et al. application may not log all of the event information necessary to arrive at an accurate determination as to what caused the wireless device malfunction.

In light of the above limitations to techniques for logging and analyzing logged information to determine the cause of a faulty event, it is desirable to be able to log all of the information both received and transmitted by a communication device during a communication session. Further, it is desirable to be able to transmit all of the logged session information to a remote device for analysis. And still further, it is desirable to be able to utilize the logged session information to very accurately determine the cause of the faulty event.

### SUMMARY OF THE INVENTION

In order to overcome the limitations of the prior art techniques, this application discloses a method and apparatus for detecting and recording wireless communication session activity, sending the recorded session activity to a computational device that operates to identify the cause of the communication session fault event.

In one embodiment of my invention, a wireless communication device initiates a communication session with a wireless communication network and records essentially all of the activity associated with the communication session, and in the event that the communication session experiences a fault event, the communication device sends the recorded session activity to a computational device that is configured to run a virtual communication session under the control of an application control module to identify the cause of the fault event.

From another aspect, I have designed a system for identifying the cause of a fault event associated with a wireless communication session that is comprised of a wireless communication device that operates to detect and record essentially all of the session activity during the course of a communication session and to send the recorded communication session activity to a computational device, which computational device operates to receive the recorded communication session activity from the wireless communication device and runs a virtual communication session under control of an application control module to identify a point in the virtual communication session in which a fault event occurs.

### BRIEF DESCRIPTION OF THE DRAWINGS

FIG. 1 is a diagram showing a wide area communication network and its relationship to two wireless LANs.

FIG. 2 is a high level functional block diagram of a mobile phone that implements the method of my invention.

FIG. 3a is a high level functional block diagram of a device configured to identify the cause of a fault event on the mobile phone.

FIG. 3b is a logic flow diagram of the operation of a virtual communication session.

FIG. 3c is a continuation of the logical flow diagram of FIG. 3b.

FIG. 3d is a continuation of the logical flow diagram of FIG. 3c.

FIG. 4a is a logical flow diagram of the method of my invention.

FIG. 4b is a continuation of the flow diagram of FIG. 4a.

### DETAILED DESCRIPTION OF THE INVENTION

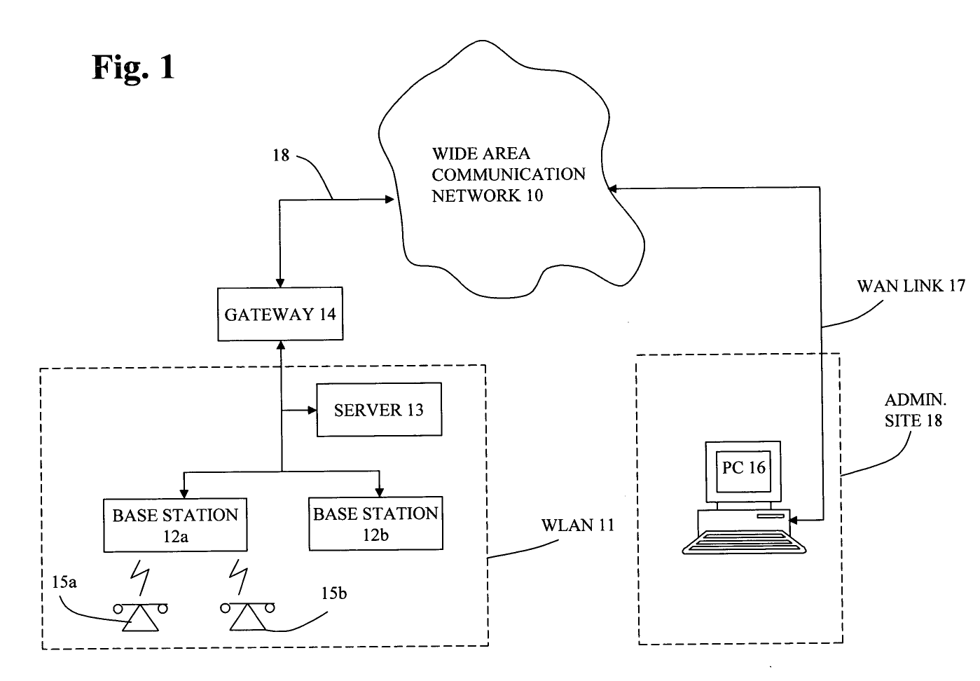

One aspect of this disclosure is to describe a method and apparatus that operates to determine the cause of a communication session fault event on a wireless communication device such as a mobile phone. FIG. 1 is a diagram showing various component parts of a wide area communication network and the relationship between this network and a wireless LAN network administrative site that includes a computational device such as a PC that is employed to identify the cause of a communication session fault that occurs on a mobile phone operating on the wireless LAN. A wide area communication network 10 is shown in relationship to a wireless LAN 11 and a PC 16 utilized by a network operator or analyst, for instance, to determine the cause of a communication session fault event. The wireless LAN 11 is connected with the communication network 10 via a gateway 14 and communication link 18 and the PC 16 is connected to the communication network 10 via a POTS line, a cable line to an internet service provider or a hi-speed leased line collectively referred to herein as communication link 17.

More specifically with reference to FIG. 1, the wireless LAN 11 includes a server 13 which generally operates to manage the routing of traffic to and from the base stations 12a and 12b. Wireless communication devices 15a and 15b, which for the purpose of this description I will refer to as mobile phones, are shown to be in communication with base station 12a and generally operate to transmit and receive messages over the wireless medium that can include voice, video or data information. Base station 12a generally operates to receive messages from the mobile phones 15a or 15b, convert these message from a wireless format to a format suitable for transmission over the wired portion of the wireless LAN 11 and they operate to receive messages from the wired portion of the wireless LAN 11, convert them into messages in a wireless format and to transmit these messages to the mobile phones 15a and 15b. The gateway 14 functions to provide security for the WLAN 11 to, for instance, prevent unauthorized access to the WLAN 11 and it can function to route messages addressed to the WLAN 11 to the correct device on the WLAN 11.

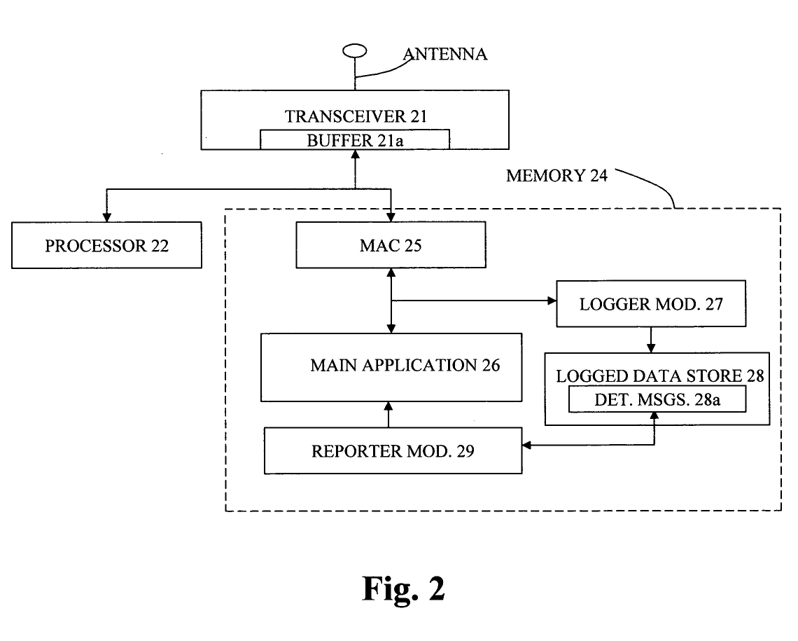

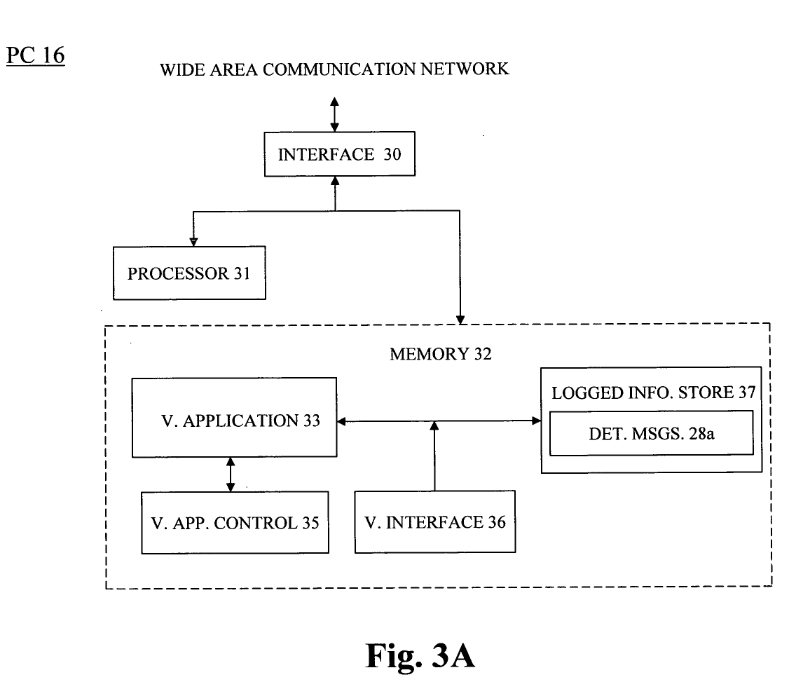

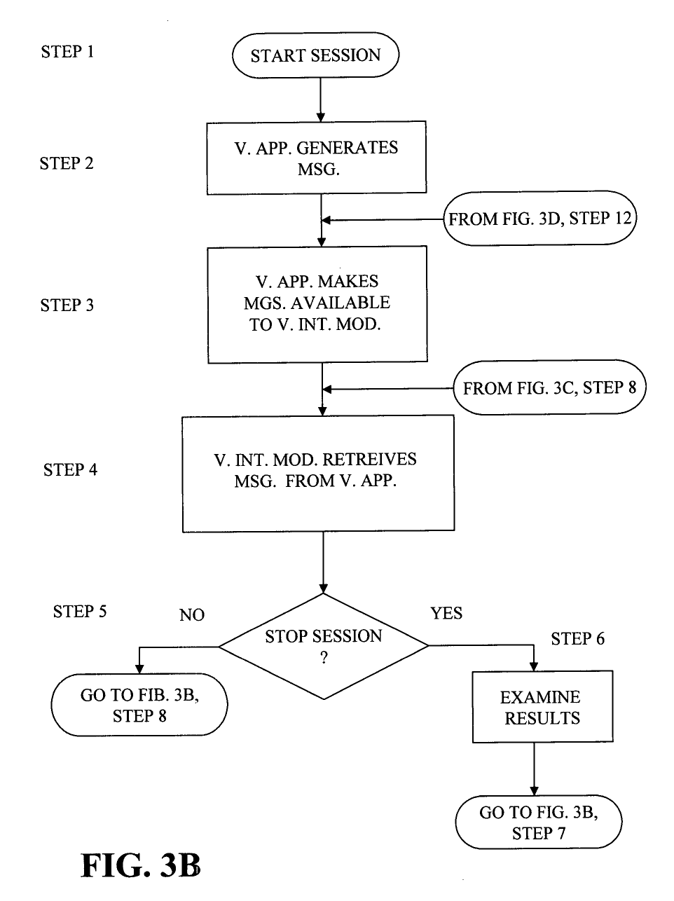

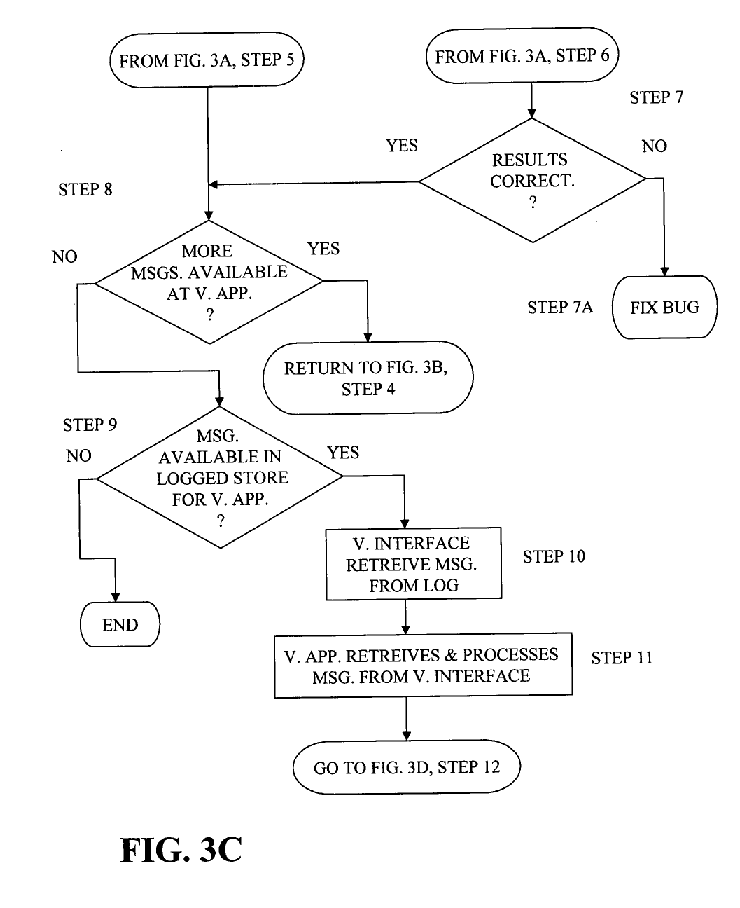

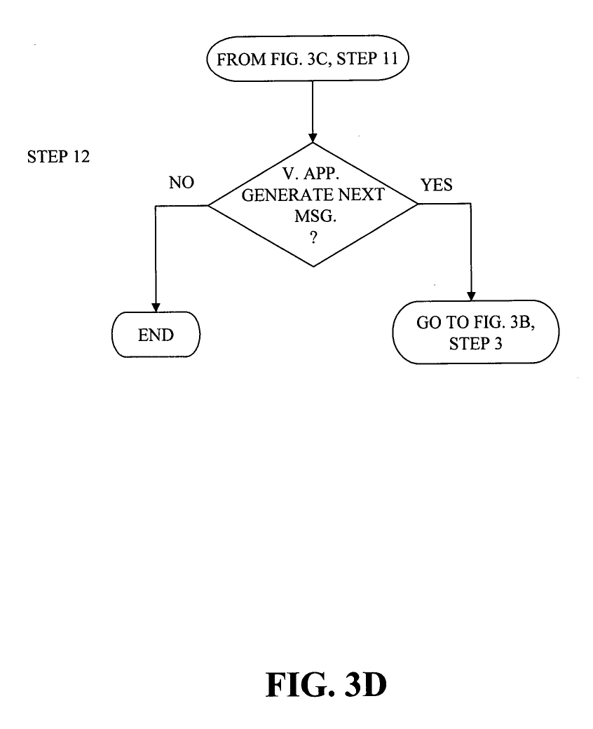

Continuing to refer to FIG. 1, the gateway 14 is connected to the WAN 10 over a link 18, which can be any type of telephone or data line for instance. The WAN 10 can be any type of public or private wide area network that is composed of some number of gateways, routers, switches and service providers that together generally operate to receive information created at one point in the network and propagate the information through the network to a destination location. A WLAN admin site 18 is connected to the WAN 10 via a link 17 that can be any type of telephone or data line. Admin site 18 includes, among other things, some sort of a computational device 16 such as a PC that incorporates an application that is used by an operator to assist with debugging communication session fault events logged at any one of the wireless communications devices, 15a or 15b, and transmitted to the admin site 18 over the WAN 10. I will describe the session logging and debugging procedures later in detail with reference to FIG. 2 and FIGS. 3a-3d.

FIG. 2 is a high level functional block diagram of one of the mobile phones 15a or 15b and shows all of the functional elements necessary to implement a first portion of the preferred embodiment of my invention that resides on a mobile phone. Specifically, the mobile phone 15a includes a transceiver 21 that generally operates to modulate signals generated by the phone for transmission over the wireless medium and to demodulate signals received by the mobile phone over the wireless medium, a processor 22 and a memory 24. The transceiver 21 includes a signal buffer 21a that is employed to temporarily store messages containing management information, for instance, until the mobile phone medium access control (MAC) 25 has the opportunity to retrieve the information. The mobile phone memory 24 is comprised of a number of software modules that generally operate to support the establishment, maintenance and termination of a communication session. Although I describe my invention in terms of software stored in a main memory, my invention could just as easily be implemented in firmware residing on a processor specially designed to be used for wireless communication applications. Specifically, memory 24 includes a low level communication module which is commonly referred to as a medium access control (MAC) module 25, a main application module 26, a sniffer/recorder or simply logger module 27, a logged data store 28 and a reporter module 29. The processor operates in combination with the main application 26 to provide most of the mobile phones functionality, including among other things establishing, maintaining and terminating a communication session. Specifically, the application 26 generates signaling messages that the mobile phone 15a sends over the air and the application 26 processes signaling messages received by the mobile phone 15a over the air that are employed to set up, maintain and terminate communication sessions. If the application 26 does not correctly generate or correctly process these signaling messages, it is likely that a communication session will unexpectedly terminate. MAC module 25 generally operates to control the mobile phone's 15a access to the wireless medium and all of the messages or information received and transmitted by mobile phone 15a are operated on by the MAC 25. All of the signaling type messaging received by mobile phone 15a and processed by the MAC 25 are then stored in the main memory 24 for later use by the main application 26.

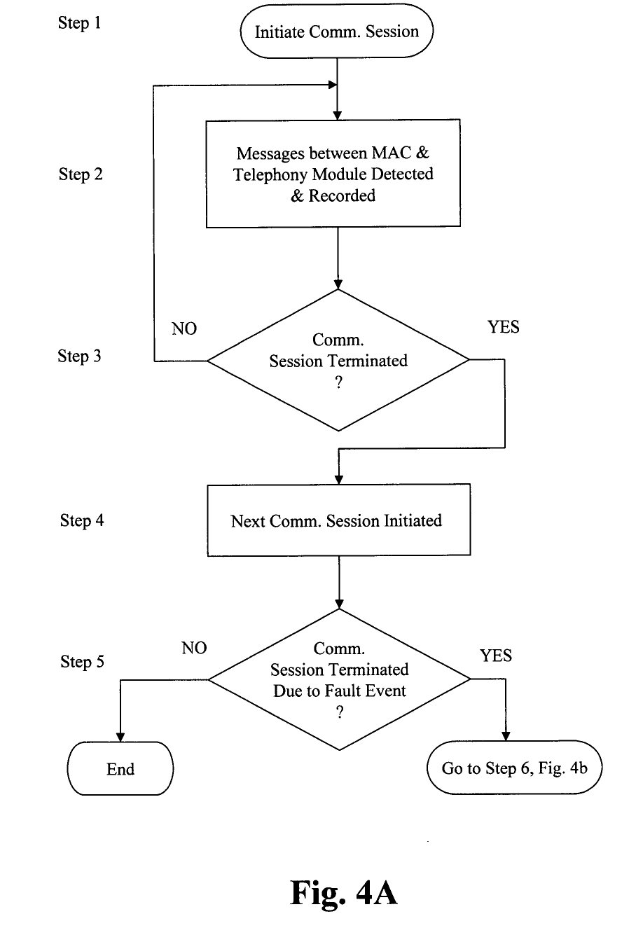

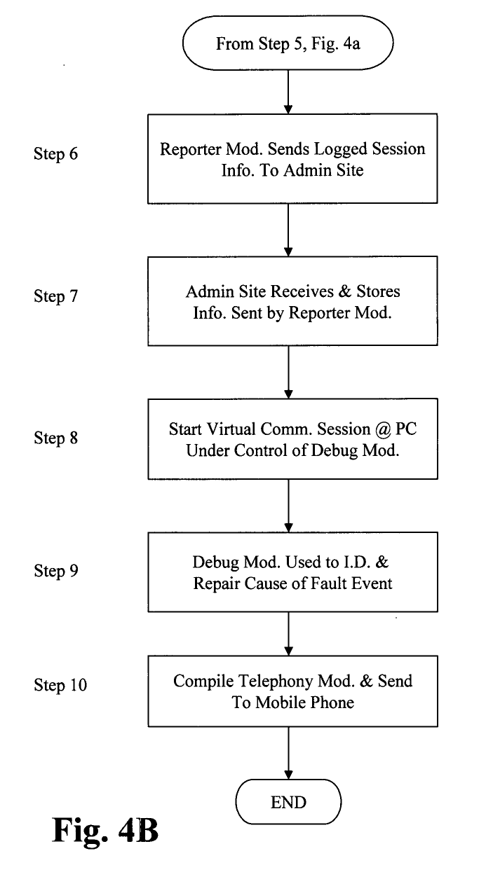

Continuing to refer to FIG. 2, I employ the sniffer/recorder or simply logger module 27, the logged data store 28 and the reporter module 29 to implement one portion of the preferred embodiment of my invention on a mobile phone. The logger module 27 operates, like a “packet sniffer”, to detect and then record, in the logged data store 28, all messages that are transmitted through a particular MAC-main application interface. More specifically, this interface is between the MAC and a particular functional module in the main application 26 that receives signaling type messaging. In this case, the functional module in main memory operates to generate signaling type messages that are made available to the MAC 25 or to receive signaling type messages made available by the MAC 25 and process them. However, it should be understood that our invention is not limited to only this type of MAC-main application interface, but can easily be modified to detect and record messages transmitted over another MAC-main application interface. The reporter module 29 operates to send a log of the communication session activity stored in the logged data store 28 to the admin site 18 shown in FIG. 1 in the event that a failure event occurs during the course of a communication session. I will refer to all messages detected by the logger module 27 as detected messages 28a and these messages will be stored by the logger module 27 in a logged data store 28 in main memory 24. All of the detected messages 28a passing through the MAC-main application interface described above during the course of a communication session will be stored in the logged data store 28. In the event that the communication session experiences a fault event that, for instance, prematurely terminates a session, the reporter module 29 can be either automatically or manually initialized to send all of the detected message 28a in the logged data store 28 to the admin site 18 of FIG. 1. So, for example, mobile phone 15a initiates a communication session by transmitting some sort of a message to base station 12a within range requesting access to a particular communication channel. The base station 12a can respond with a message indicating to the mobile phone 15a that the channel is available and the traffic from the phone will be accepted. The mobile phone 15a can then transmit messages to the base station 12a until the session is unexpectedly terminated. The mobile phones request message, the base stations response message and all of the signaling messages subsequently transmitted by the mobile phone can be detected by the logger module 27 and stored in the logged data store 28 up to the point that the communication session is unexpectedly terminated. At this point, the mobile phone user can attempt to re-establish a communication session with the base station 12a and manually initialize the reporter module 29 functionality or when the mobile phone 15a re-establishes a communication session with the base station the telephony application 26 can be programmed to automatically initialize the reporter module 29 functionality. Regardless of the means used to initialize the reporter module 29, the module operates to send all of the detected messages 28a logged in the data store 28 and sends them to the MAC 25 specifying that they be transmitted to the destination address of the admin site 18. One advantage of detecting and storing session information from the beginning of a session is that all of the information possibly needed by the admin site for the debugging process is captured and available for analysis. The process by which a mobile phone detects and logs messages of information passing between the MAC and the telephony application for later transmission to an admin site will be described in detail later with reference to FIG. 4.

FIG. 3a is a high level functional block diagram showing those functional elements of a computational device 16 such as a PC necessary for the operation of a second portion of the preferred embodiment of my invention that is incorporated into the admin site. This second portion operates in conjunction with the first portion described earlier with reference to FIG. 2. The PC includes a communication network interface device 30 which could be any sort of modem that operates to convert signals in the communication network 10 format to signals in a format that can be used by the PC. Communication network signals can be formatted according to the well know Ethernet standard, for instance, and signals internal to the PC can be formatted according to the well known PCI format for instance. The communication network interface device 30 is in communication with a processor 31 and memory 32. The memory 32 includes a virtual application module 33, a virtual application control module 35 which can be a debugging application, a virtual interface module 36, which simulates the operation of the MAC on mobile phone, and a logged information store 37 which is a region in PC memory used to store the detected messages 28a previously described with reference to FIG. 2. Generally, the processor 31 operates in conjunction with the virtual application 33, the virtual application control module 35, the logged information store 37 and the virtual interface module 36 all stored in the memory 32 to conduct a virtual mobile phone communication session or simply virtual communication session that replicates or mirrors essentially all of the messaging activity that transpires between the MAC 25 and the main application 26 of FIG. 2 during an actual communication session at mobile phone 15a prior to a fault event. In this case, the virtual application 33 can be composed of the same code as that in the main application module 26 of FIG. 2. Continuing to refer to FIG. 3a and specifically to the functional modules included in PC memory 32, as described above, the virtual application 33 utilizes information stored in the logged information store 37 to perform all of the operations ordinarily performed at mobile phone 15a during the time it initiates, maintains and terminates a communication session, which in this case is unexpectedly terminated due to a fault event. More specifically, the virtual application 33 operates in coordination with the virtual interface module 36 to utilize the detected signaling messages stored in the logged information store 37 to run a virtual communication session. The virtual interface module 36 includes code that responds to messages generated by the main application requesting input from it to retrieve a detected message from the logged information store 37 and send it to the virtual application 33. The virtual interface module 36 also includes code that detects the resultant output of the virtual application 33 and verifies that this output matches the output from the main application module 26 that is recorded earlier during the actual communication session on the mobile phone 15a, stored and then sent to the admin site and stored in the logged information store 37 on the PC. The logged information store 37 includes a listing of the detected messages of session information in the order that they were detected during the actual communication session at the mobile phone 15a. An example of such an ordered list is provided in Table 1 below.

TABLE 1
${mac}_{-} hl [ 0 ] , 0 x01 , 0 x99$ ${hl}_{-} mac [ 0 ] , 0 x08 , 0 x0d , 0 xca , 0 x10$ ${mac}_{-} hl [ 0 ] , 0 x02 , 0 x11 , 0 x72$ ${hl}_{-} mac [ 0 ] , 0 x03 , 0 x12 , 0 x01$ $⋮$ ${hl}_{-} mac [ 0 ] , 0 z 07 , 0 x02 , 0 x00 , 0 xf 0$

As mentioned above, Table 1 includes a listing of detected messages of session information in the order that they were detected and recorded during the actual communication session at mobile phone 15a. A complete set of the information contained in each detected message is included in each line of the table in hexadecimal format. The header information included in each detected message indicates whether the message is generated by the main application 33 (hl_mac) or by the virtual interface module 36 (mac_hl) during the actual communication session on the mobile phone 15a. At the point that the operator initiates the virtual communication session, the virtual application 33 can generate an application message and makes this message available to the virtual interface module 36. The virtual interface module 36 retrieves the application message, message “hl_mac[0], 0x08, 0x0d, 0xca, 0x10” in Table 1 for instance, compares it to the corresponding message in the logged information store 37 and can then, if there are no more application messages available to it at the virtual application 33, retrieve a next message from the logged information store 37 that is labeled to be sent to the virtual application 33 which can be the message “mac_hl[0], 0x02, 0x11, 0x72” in Table 1 for instance, and sends it to the virtual application 33. The virtual application 33 operates on this message in some manner and then returns a result message to the virtual interface module 36 which performs the above describe verification and if the results match those already stored in the order list, namely the second message in the ordered list, then the process continues. If the results do not match the virtual communication session can be programmed to stop and the developer can examine the results to determine why the comparison failed.

Referring to FIG. 3b, and more specifically with reference to the operation of a virtual communication session, once the PC 16 at the admin site has received the detected message 28a from the mobile phone 15a and stored this information in the logged information store 37, in step 1 the developer can start the virtual communication session by entering the virtual communication session control or debugging module 35 and selecting a function that starts the virtual communication session. The debugging module 35 used in one embodiment of my invention is a commercially available open source tool offered by Eclipse, but my invention is not only limited to using this tool as any C compatible debugger on the market can be employed as well. Further, it should be understood that debuggers generally provide a program control interface that allows a programmer or system administrator to do such things as executing only one application program instruction at a time, examining and/or modifying PC registers and setting breakpoints at particular locations in the main application. As mentioned above, after initializing the debugging process, in step 2 the virtual application module 33 typically can generate an application message such as requesting a channel over which to transmit voice signals, and make the message available to the virtual interface module 36. In step 4 the virtual interface module 36 can retrieve the message from the virtual application 33 and in step 5, the operation of the virtual application 33 can be manually stopped by the developer using the debugger 35 for a number of different reasons so that in step 6 an application developer can examine the contents of the messages generated by the main application. The debugger 35 can also be programmed, as described above, to automatically stop the operation of the virtual application 33 at particular strategic points to allow the developer to examine the contents of messages generated by the virtual application 33. The objective of the debugging process of my invention is for the developer to observe the traffic between the virtual interface and the virtual application during the entire course of a virtual communication session so that they can identify the cause of a session fault event. Once the cause of the event is detected, the developer can then determine how to proceed to correct the fault. In many cases the cause of the faulty event is a “bug” or programming error in the virtual application. As the PC 16 is running the virtual application 33 in conjunction with the debugger module 35, the administrator has the opportunity to correct the virtual application error and then re-run the virtual communication session to determine whether or not the bug fix corrects the error. This is a very efficient means for fixing programming errors as it is not necessary, after modifying the virtual application 33, to recompile and the load it onto the mobile phone 15a for testing. Continuing to refer to step 6, regardless of the method used to stop the virtual communication session, after examining the results of the resultant message generated by the virtual application 33 in step 3, the process proceeds to step 7 of FIG. 3c.

Referring now to FIG. 3c, in step 7 if the results of the developer's examination in step 6 indicate that the contents of the result message generated by the virtual application 33 in step 3 are correct, then the process proceeds to step 8, of FIG. 3c, otherwise the process proceeds to step 7a and the developer fixes that problem. At the point in time that the developer determines that the bug has been fixed, by running the virtual application 33 in the virtual communication session environment, the application code can then be recompiled and loaded onto the mobile phone with great confidence that the programming error has been corrected. In step 8, if there are more application messages available to the virtual interface module 36 the process returns to step 4 in FIG. 3b, otherwise the process proceeds to step 9 where the virtual interface module 36 examines to logged information store 37 to determine if there are any messages 28a for the virtual application 33. If there are, then in step 10, the virtual interface modules 36 retrieves the message and makes it available to the virtual application 33 and in step 11 the virtual application 33 retrieves the message from the virtual interface 36 and processes the message. On the other hand, if in step 9 it is determined that there are no messages in the logged store to be sent to the virtual application 33, then the process ends and the virtual communication session comes to an end.

Referring now to FIG. 3d, in step 12 if the virtual application 33 generates a message as the result of receiving and process the message in step 11, then the process returns to FIG. 3b, step 3. Otherwise the process ends and the virtual communication session is terminated. As with my description of that portion of my invention implemented on a mobile phone, although I have described that portion of the preferred embodiment of my invention that is included on the PC at the admin site as being implemented in software, it could just as easily be implemented in firmware on a processor designed to accommodate such functionality. So, for instance, some or all of the virtual application 33, the debug module 35 and the virtual interface module 36 can be implemented in firmware.

The operation of the preferred embodiment of my invention will now be described with reference to the logical flow diagram shown in FIG. 4a and FIG. 4b. In step 1 of FIG. 4a the mobile phone 15a initiates a communication session by transmitting a request message to access the medium to a base station that is within range, base station 12a for instance. In step 2, this request message is generated by the main application module 26 in FIG. 2 and detected and stored in the logged data store 28 by logger 27 as it is sent to the MAC 25 where it is queued waiting for access to the medium to become free. Subsequent to the access request being transmitted by the mobile phone 15a, the mobile phone will receive a response message from the base station 12a indicating, among other things, that it is available to receive the mobile phones voice traffic. After receiving the response message from the base station 12a, the mobile phone 15a MAC 25 sends the response message to the main application module 26. The logger 27 detects the response message as it is being sent from the MAC 25 to the telephony module 26 and stores the message in the logged data store 28. In step 3, if the communication session is still active, the process loops back to step 2 and the logger 27 continues to detect messages sent back and forth between the MAC 25 and the main application 26. The process remains in this loop for the duration of the communication session. If the communication session is terminated, the process proceeds to step 4 where a next communication session is initiated. At the point that the next communication session is initiated, in step 5 a determination is made as to whether or not the last communication session ended normally, that is, not due to a fault event or unexpectedly due to a fault event. This determination can be made either by the mobile phone user or automatically by the mobile phone main application module 26 of FIG. 2. In the event that this determination depends on the judgment of the mobile phone user, then the mobile phone 15a will include a function that the user can activate that initializes the reporter module 29 described with reference to FIG. 2 which operates to send some or all of the session information logged during the course of the previous communication session to PC 16 located at the admin site 18. This function can be activated by a singe button on the mobile phone or it can be activated by selecting the function on a menu that is displayed by the phone. In the event that this determination is arrived at automatically, the main application module 26 needs to include some functionality that is able to detect the premature termination of a communication session and initialize the reporter module to send some or all of the session information to the admin site. An exception handler, for instance, can be included in the main application 26 to perform this functionality. At this point in the process, if the communication session is not terminated due to a fault event, then the process ends. However, in the event that the communication session is terminated unexpectedly as the result of a fault event, the process proceeds to step 6 in FIG. 4b where the main application module 26 initializes the reporter module 29 which operates to retrieve some or all of the detected messages 28a stored in the logged data store 28 and send them to the PC 16 located at the admin sit 18. There are a number of causes for the unexpected termination of a communication session, chief among these causes are software bugs typically found in one of the mobile phones software or firmware modules such as the main application module.

Continuing to refer to FIG. 4b, in step 7 the PC 16 at the admin site described in FIG. 1 and FIG. 2 receives the detected messages 28a sent by the mobile phone 15a and stores them the logged information store 37 described with reference to FIG. 3. In step 8, the application developer or analyst can start the debugging process by initializing the virtual application control or debug module 35 stored in the memory 32 of PC 16. As described with reference to FIG. 3, the debug module 35 operates to effectively control the operation of the virtual application 33 also located in memory 32 in a number of different ways. The debug module 35 can, among other things, start and stop the running of the virtual application 33, it can single step through the instruction lines of the virtual application, and it can be used to insert break points into the virtual application. All of these techniques aid in analyzing the cause of a fault event in a communication session. As described in detail with reference to FIG. 3, a virtual communication session is run on the PC 16 utilizing the information in the logged information store 37, the virtual MAC 36, the virtual application 33 and is under the control of the debugging module 35. In step 9, at some point in the debugging process, the network administrator identifies and repairs the cause of the fault event usually by editing the code in the virtual application 33, and in step 10 the edited code is recompiled and this new version of the virtual application is sent over the communication network 10 to the mobile phone 15a. The mobile phone 15a receives the new version of the main application 26 (which is the compiled virtual application) and eventually replaces the old version of the main application with the newer version and the process ends.

Although, in the preferred embodiment of my invention, the admin site 18 is located remotely from the WLAN 11 on which the mobile phone 15a is registered to operate, this admin site may be local to the WLAN on which the mobile phone is registered to operate. In either case, the operation of the process of my invention is not affected. Further, even though I have described the preferred embodiment of my invention as being implemented with separate software modules at both the mobile phone 15a and the PC 16, my invention could just as easily be implemented in a single logger/reporter software or firmware module in the mobile phone 15a and in a single debugger module 35 in the PC which includes the virtual interface module 36, the virtual application control module 35 and the virtual application 33.

The forgoing description, for purposes of explanation, used specific nomenclature to provide a thorough understanding of the invention. However, it will be apparent to one skilled in the art that specific details are not required in order to practice the invention. Thus, the forgoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications, they thereby enable others skilled in the art to best utilize the invention and various embodiments with various modifications as are suited to the particular use contemplated. It is intended that the following claims and their equivalents define the scope of the invention.

I claim:

1. A method for identifying fault events associated with a communication session recorded by a wireless communications device, the method comprising:
the wireless communication device initiating a communication session with a wireless communication network;
the wireless communication device logging communication session activity during the course of the communication session;
the wireless communication device sending all of the logged communication session activity to a computational device if the communication session unexpectedly ends; and
the computational device receiving the logged communication session activity and running a virtual communication session under the control of a virtual application control module to examine the communication session activity in order to determine the cause of the unexpected end to the communication session.

2. The method of claim 1 wherein the examination of the communication session activity is comprised of:
the virtual application control module initializing the virtual application module to generate a first application message;
the virtual application module making the first application message available to the virtual interface module;
the virtual interface module retrieving the first application message from the virtual application; and
the virtual application control module stopping the operation of the virtual application module in order to permit examination of the contents of the first application message.

3. The method of claim 1 in which the wireless communications device is one of a mobile phone, a PDA and a mobile computer.

4. The method of claim 1 in which the wireless communication network is comprised of at least one wireless LAN.

5. The method of claim 1 in which the logging of communication session activity includes detecting and recording messaging activity at an interface to a main application.

6. The method of claim 1 in which the communication session ends unexpectedly due to a fault event.

7. The method of claim 1 in which the computational device is a PC.

8. The method of claim 4 wherein the at least one wireless LAN includes the mobile communications device and the computational device.

9. The method of claim 1 in which the wireless communications device and the computational device are located in different wireless LANs.

10. A wireless communication device operable to log and report wireless communication session activity, the wireless communication device comprising:
a logger for detecting and recording communication session activity; and
a reporter for transmitting all of the recorded messages to a computational device that is remote to the wireless communications device if the wireless communication session unexpectedly ends.

11. The wireless communications device of claim 10 wherein the wireless communications device is one of a mobile phone, a PDA and a mobile computer.

12. The wireless communications device of claim 10 wherein the logged communication session activity is comprised of all messages transmitted through an interface of a main application on the wireless communications device.

13. The wireless communications device of claim 10 wherein the logger is comprised of a detector for detecting all of the messages transmitted through the interface of the main application on the wireless communications device and a recorder for storing all of the messages transmitted through the interface of the main application on the wireless communications device.

14. The wireless communications device of claim 10 wherein the reporter transmits the recorded messages if the wireless communications device unexpectedly ends due to a fault event occurring at the wireless communications device.

15. The wireless communications device of claim 10 wherein the computational device is operable to receive the messages sent to it by the reporter and to use these messages to run a virtual communication session under the control of a virtual application control module.

16. A computational device comprising:
a network interface device;
a processor coupled to the network interface device; and
a memory coupled to the processor, the memory including
a store of event activity associated with the wireless communication session;
a virtual application;
a virtual interface module; and
a virtual application control module for controlling the virtual application, which operates in conjunction with the virtual interface module to run a virtual communication session, to stop the operation of the virtual application in order to examine the wireless communication session event activity contents.

17. The computational device of claim 16 is one of a mobile phone, a PDA and a mobile computer.

18. The computational device of claim 16 wherein the event activity is comprised of a least one message detected by an event logger located on a wireless communications device and transmitted to the computational device.

19. The computational device of claim 16 wherein the virtual application operates to control the start, maintenance and termination of the virtual wireless communication session.

20. The computational device of claim 16 wherein the virtual application control module is a debugger module.
